(19) United States
(12) Patent Application Publication
(10) Pub. No.: US 2026/0090422 A1
(43) Pub. Date: Mar. 26, 2026

(54) INTERCONNECT SUBSTRATE AND METHOD OF MAKING THE SAME

(71) Applicant: SHINKO ELECTRIC INDUSTRIES CO., LTD., Nagano (JP)

(72) Inventors: Masahiro SUNOHARA, Nagano (JP); Jun YOSHIIKE, Nagano (JP); Noriyoshi SHIMIZU, Nagano (JP)

(21) Appl. No.: 19/340,089

(22) Filed: Sep. 25, 2025

(30) Foreign Application Priority Data
Sep. 26, 2024 (JP) 2024-167103

(51) Int. Cl. H01L 23/498; H01L 23/15

(52) U.S. Cl. CPC H10W 70/65; H10W 70/692

(57) ABSTRACT

An interconnect substrate includes a core layer made of glass and a first interconnect layer disposed on a surface of the core layer, wherein the core layer has one or more first cut-outs located on an outer side of the surface in plan view, wherein, in plan view, the surface of the core layer has a plurality of corners, and the one or more first cut-outs include at least a portion bent along each of the corners of the surface, and wherein in a cross-sectional view of each of the one or more first cut-outs, a connection portion between a side portion and a bottom portion is curved.

### CROSS-REFERENCE TO RELATED APPLICATIONS

The present application is based on and claims priority to Japanese Patent Application No. 2024-167103 filed on Sep. 26, 2024, with the Japanese Patent Office, the entire contents of which are incorporated herein by reference.

### FIELD

The disclosures herein generally relate to interconnect substrates and methods of making an interconnect substrate.

### BACKGROUND

As known in the art, interconnect substrates may include interconnect layers and insulating layers laminated on core layers. In such an interconnect substrate, a cut-out may be provided on the periphery of a core layer. The cut-out is formed, for example, by a dicing blade having a sharp edge at the tip, which results in the presence of an edge in the cut-out. The cut-out is covered with a resin different from the resin constituting the interlayer insulating layers, for example (Patent Document 1).

A glass core layer may sometimes be used in an interconnect substrate. Since the thermal expansion coefficient of the glass core layer is significantly different from that of the resin constituting the insulating layers, internal fractures may develop in the glass due to the thermal contraction force caused by the difference in the thermal expansion coefficients.

There may be a need to suppress internal fractures in the glass in an interconnect substrate having a core layer made of glass.

### RELATED-ART DOCUMENTS

### Patent Document

[Patent Document 1] Patent No. 5297139

### SUMMARY

According to an aspect of the embodiment, an interconnect substrate includes a core layer made of glass and a first interconnect layer disposed on a surface of the core layer, wherein the core layer has one or more first cut-outs located on an outer side of the surface in plan view, wherein, in plan view, the surface of the core layer has a plurality of corners, and the one or more first cut-outs include at least a portion bent along each of the corners of the surface, and wherein in a cross-sectional view of each of the one or more first cut-outs, a connection portion between a side portion and a bottom portion is curved.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIGS. 1A and 1B are drawings illustrating an example of an interconnect substrate according to the first embodiment;

FIG. 2 is a drawing illustrating an example of a manufacturing process of the interconnect substrate according to the first embodiment;

FIGS. 3A through 3D are drawings illustrating the example of the manufacturing process of the interconnect substrate according to the first embodiment;

FIGS. 4A through 4C are drawings illustrating the example of the manufacturing process of the interconnect substrate according to the first embodiment;

FIG. 5 is a plan view illustrating an example of an interconnect substrate according to the first variation of the first embodiment; and

FIG. 6 is a plan view illustrating an example of an interconnect substrate according to the second variation of the first embodiment.

### DESCRIPTION OF EMBODIMENTS

Embodiments of the invention will be described below with reference to the accompanying drawings. In these drawings, the same components are denoted by the same reference numerals, and duplicate descriptions may be omitted.

### First Embodiment

### Structure of Interconnect Substrate of First Embodiment

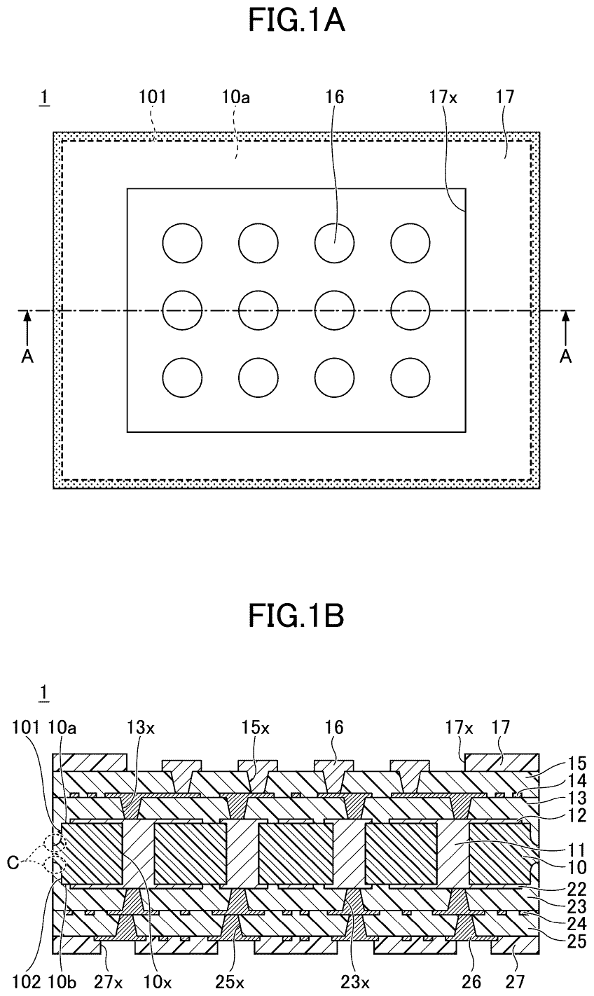

FIGS. 1A and 1B are drawings illustrating an example of an interconnect substrate according to a first embodiment. FIG. 1A is a plan view and FIG. 1B is a cross-sectional view taken along the line A-A in FIG. 1A.

Referring to FIGS. 1A and 1B, an interconnect substrate 1 is structured such that interconnect layers and insulating layers are laminated on both surfaces of a core layer 10.

Specifically, the interconnect substrate 1 includes an interconnect layer 12, an insulating layer 13, an interconnect layer 14, an insulating layer 15, an interconnect layer 16, and a solder resist layer 17 sequentially laminated on a first surface 10a of the core layer 10. On a second surface 10b of the core layer 10, an interconnect layer 22, an insulating layer 23, an interconnect layer 24, an insulating layer 25, an interconnect layer 26, and a solder resist layer 27 are sequentially laminated.

In the first embodiment, for convenience, the solder resist layer 17 side of the interconnect substrate 1 is referred to as an upper side or a first side, and the solder resist layer 27 side is referred to as a lower side or a second side. The surface of a portion oriented in the same direction as the solder resist layer 17 side is referred to as a first surface or an upper surface, and the surface of the portion oriented in the same direction as the solder resist layer 27 side is referred to as a second surface or a lower surface. However, the interconnect substrate 1 may be positioned upside down when used, or may be arranged at any angle. The plan view refers to the view of an object as seen from the direction normal to the first surface 10a of the core layer 10, and the plan shape refers to the shape of an object as seen from the direction normal to the first surface 10a of the core layer 10.

The core layer 10 is made of glass. Although the kind of glass constituting the core layer 10 is not limited, alkali-free glass, quartz glass, borosilicate glass, or the like may be used, for example. The thickness of the core layer 10 is, for example, in the range of approximately 100 to 1000 μm. The core layer 10 has through holes 10x that extend through the core layer 10 in the thickness direction. The plan shape of each of the through holes 10x is, for example, circular.

The core layer 10 has, in plan view, the first surface 10a and a first cut-out 101 located on the outer side thereof. The core layer 10 has, in plan view, the second surface 10b and a second cut-out 102 located on the outer side thereof. The widths of the first cut-out 101 and the second cut-out 102 may approximately be, for example, 0.05 mm or more and 0.5 mm or less. The depths of the first cut-out 101 and the second cut-out 102 may approximately be, for example, 0.05 mm or more and 0.3 mm or less.

In plan view, the first surface 10a of the core layer 10 has a plurality of corners, and the first cut-out 101 includes at least a portion bent along the perimeter of each corner of the first surface 10a. In plan view, the second surface 10b of the core layer 10 has a plurality of corners, and the second cut-out 102 includes at least a portion bent along the perimeter of each corner of the second surface 10b.

In the example illustrated in FIGS. 1A and 1B, the first surface 10a and the second surface 10b of the core layer 10 are square or rectangular, and each surface has four corners. In the example illustrated in FIGS. 1A and 1B, in plan view, the first cut-out 101 includes portions bent along the perimeters of the four corners of the first surface 10a, and is formed along the perimeter of the first surface 10a in a closed-loop shape. The second cut-out 102 includes portions bent along the four corners of the second surface 10b, and is formed along the perimeter of the second surface 10b in a closed-loop shape.

In the first cut-out 101 and the second cut-out 102, the connection portion C between the side portion and the bottom portion is curved in cross-sectional view, without any sharp corner. The connection portion C may be an arc shape, an elliptical arc shape, or any other shape similar to an arc or an elliptical arc in cross-sectional view. When the connection portion C is an arc shape in cross-sectional view, the radius of the arc may approximately be, for example, 0.05 mm or more and 0.3 mm or less.

The side portion of the first cut-out 101 connects to the first surface 10a and extends from the first surface 10a toward the second surface 10b. The bottom portion connects to the lateral surface of the core layer 10 and extends from the lateral surface toward the through holes 10x. In the first cut-out 101, the boundaries between the side portion, the bottom portion, and the connection portion need not be clear. The crucial point is that no sharp corner exists in the region from the portion abutting the first surface 10a to the portion abutting the lateral surface of the core layer 10.

The side portion of the second cut-out 102 connects to the second surface 10b and extends from the second surface 10b toward the first surface 10a. The bottom portion connects to the lateral surface of the core layer 10 and extends from the lateral surface toward the through holes 10x. In the second cut-out 102, the boundaries between the side portion, the bottom portion, and the connecting portion need not be clear. The crucial point is that no sharp corner exists in the region from the portion abutting the second surface 10b to the portion abutting the lateral surface of the core layer 10.

The interconnect layer 12 is disposed on the first surface 10a of the core layer 10. The interconnect layer 22 is disposed on the second surface 10b of the core layer 10. The interconnect layer 12 and the interconnect layer 22 are electrically connected by through interconnects 11 formed in the through holes 10x. Each of the interconnect layers 12 and 22 is patterned in a predetermined plan shape. The interconnect layers 12 and 22 and the through interconnects 11 may be made of, for example, copper (Cu). The thicknesses of the interconnect layers 12 and 22 are, for example, in the range of approximately 10 to 40 μm. The interconnect layer 12, the interconnect layer 22, and the through interconnects 11 may be seamlessly formed as a single piece.

The insulating layer 13 is an interlayer insulating layer disposed on the first surface 10a of the core layer 10 and covering the interconnect layer 12 and the first cut-out 101. The insulating layer 13 fills the entirety of the first cut-out 101. The material of the insulating layer 13 may be an insulating resin or the like mainly composed of, for example, an epoxy-based resin or a polyimide-based resin. The thickness of the insulating layer 13 may be, for example, in the range of approximately 30 to 40 μm. The insulating layer 13 may contain a filler such as silica (SiO₂).

Via holes 13x are formed in the insulating layer 13 to extend through the insulating layer 13 and reach the upper surface of the interconnect layer 12. The via holes 13x may each be an inverted truncated conical hole for which the diameter of the opening toward the insulating layer 15 is larger than the diameter of the opening at the upper surface of the interconnect layer 12.

The interconnect layer 14 is formed on the first side of the insulating layer 13. The interconnect layer 14 includes via interconnects filling the via holes 13x and an interconnect pattern formed on the upper surface of the insulating layer 13. The interconnect pattern is electrically connected to the interconnect layer 12 via the via interconnects. The material of the interconnect layer 14 and the thickness of the interconnect pattern may be substantially the same as those of the interconnect layer 12, for example.

The insulating layer 15 is formed on the upper surface of the insulating layer 13 so as to cover the interconnect layer 14. The material and the thickness of the insulating layer 15 may be substantially the same as those of the insulating layer 13, for example. The insulating layer 15 may contain a filler such as silica (SiO₂).

Via holes 15x are formed in the insulating layer 15 to extend through the insulating layer 15 and reach the upper surface of the interconnect layer 14. The via holes 15x may each be an inverted truncated conical hole for which the diameter of the opening toward the solder resist layer 17 is larger than the diameter of the opening at the upper surface of the interconnect layer 14.

The interconnect layer 16 is formed on the first side of the insulating layer 15. The interconnect layer 16 includes via interconnects filling the via holes 15x and pads formed on the upper surface of the insulating layer 15. The pads are electrically connected to the interconnect layer 14 through the via interconnects. The material of the interconnect layer 16 and the thickness of the pads may be substantially the same as those of the interconnect layer 12, for example. The thickness of the pads may be larger than that of the interconnect layer 12. The interconnect layer 16 may also include an interconnect pattern in addition to the pads.

The solder resist layer 17 is a protective insulating layer located as the outermost layer on the first side of the interconnect substrate 1, and is formed on the upper surface of the insulating layer 15 while exposing the interconnect layer 16. The solder resist layer 17 may be formed in a closed-loop shape so as to have the opening 17x exposing the interconnect layer 16, for example. The pads of the interconnect layer 16 exposed in the opening 17x may be used for electrical connections with an electronic component such as a semiconductor chip, for example. The solder resist layer 17 may be formed of, for example, photosensitive epoxy-based insulating resin or acrylic-based insulating resin. The thickness of the solder resist layer 17 is, for example, in the range of approximately 15 to 35 km.

On the surface of the interconnect layer 16 exposed in the opening 17x, a metal layer may be formed, or an organic coating may be formed by applying an antioxidant treatment such as organic solderability preservative (OSP) treatment. Examples of the metal layer include an Au layer, a Ni/Au layer (a metal layer made by laminating a Ni layer and an Au layer in this order), a Ni/Pd/Au layer (a metal layer made by laminating a Ni layer, a Pd layer, and an Au layer in this order), and a Sn layer.

The insulating layer 23 is an interlayer insulating layer disposed on the second surface 10b of the core layer 10 and covering the interconnect layer 22 and the second cut-out 102. The insulating layer 23 fills the entirety of the second cut-out 102. The material and the thickness of the insulating layer 23 may be substantially the same as those of the insulating layer 13, for example. The insulating layer 23 may contain a filler such as silica (SiO₂).

Via holes 23x are formed in the insulating layer 23 to extend through the insulating layer 23 and reach the lower surface of the interconnect layer 22. The via holes 23x may each be a truncated conical hole for which the diameter of the opening toward the insulating layer 25 is larger than the diameter of the opening at the lower surface of the interconnect layer 22.

The interconnect layer 24 is formed on the second side of the insulating layer 23. The interconnect layer 24 includes via interconnects filling the via holes 23x and an interconnect pattern formed on the lower surface of the insulating layer 23. The interconnect pattern is electrically connected to the interconnect layer 22 via the via interconnects. The material and the thickness of the interconnect layer 24 may be substantially the same as those of the interconnect layer 12, for example.

The insulating layer 25 is formed on the lower surface of the insulating layer 23 so as to cover the interconnect layer 24. The material and the thickness of the insulating layer 25 may be substantially the same as those of the insulating layer 13, for example. The insulating layer 25 may contain a filler such as silica (SiO₂).

Via holes 25x are formed in the insulating layer 25 to extend through the insulating layer 25 and reach the lower surface of the interconnect layer 24. The via holes 25x may each be a truncated conical hole for which the diameter of the opening toward the solder resist layer 27 is larger than the diameter of the opening at the lower surface of the interconnect layer 24.

The interconnect layer 26 is formed on the second side of the insulating layer 25. The interconnect layer 26 includes via interconnects filling the via holes 25x and an interconnect pattern formed on the lower surface of the insulating layer 25. The interconnect pattern is electrically connected to the interconnect layer 24 via the via interconnects. The material and the thickness of the interconnect layer 26 may be substantially the same as those of the interconnect layer 12, for example.

The solder resist layer 27 is a protective insulating layer located as the outermost layer on the second side of the interconnect substrate 1, and is formed on the lower surface of the insulating layer 25 to cover the interconnect layer 26. The material and thickness of the solder resist layer 27 may be substantially the same as those of the solder resist layer 17, for example. The solder resist layer 27 has openings 27x, and portions of the lower surface of the interconnect layer 26 are exposed within the openings 27x. The plane shape of each of the openings 27x may be, for example, circular. The interconnect layer 26 exposed in the openings 27x may be used as pads for electrical connections to a mounting substrate such as a motherboard. If necessary, a metal layer of the kind previously described may be formed on the lower surface of the interconnect layer 26 exposed in the openings 27x, or an oxidation prevention treatment such as OSP treatment may be applied.

Generally, an interconnect substrate is such that the glass core layer, the interconnect layers, and the insulating layers have different coefficients of thermal expansion. For example, the thermal expansion coefficient of a glass core layer is in the range of approximately 3 to 15 ppm/° C., and the thermal expansion coefficient of interconnect layers made of copper is about 17 ppm/° C. The thermal expansion coefficient of insulating layers made of resin is in the range of approximately 10 to 100 ppm/° C. As a result, an increase in the temperature of the interconnect substrate generates thermal contraction force at the center region of the interconnect substrate, causing tensile stress in the vertical direction and the concentration of the stress at the periphery of the glass core layer. The strength of the glass may be insufficient, and internal fracture may occur, starting from the periphery.

In order to suppress internal fracture, a cutout as shown in Patent Document 1 may be formed at the periphery of the core layer. However, with the cut-out having an edge (i.e., a corner in cross-sectional view), stress is concentrated at the corner of the cut-out, and internal fracture may occur starting from the corner of the cut-out. It cannot be said that the effect of internal fracture suppression is sufficient.

In contrast, the interconnect substrate 1 is provided with the first cut-out 101 and the second cut-out 102 at the periphery of the glass core layer 10, such that the connecting portions between the side portions and the bottom portions are curved in cross-sectional view. That is, the first cut-out 101 and the second cut-out 102 do not have corners, which results in the dispersion of stress, thereby effectively suppressing the internal fracture of the glass core layer 10.

In general, glass core layers have thermal expansion coefficients close to those of interconnects and semiconductor materials, and, thus, are unlikely to have problems such as warpage due to temperature change. Because of this, interconnect substrates having glass core layers are often used at higher temperatures than other types of interconnect substrate. When an interconnect substrate is used at higher temperatures, a void or the like that may exist in the interconnect substrate may cause an internal fracture in the glass due to air expansion. In consideration of this, it is necessary to ensure that voids do not occur in interconnect substrates having glass core layers, more so than in the past. If the cut-outs have corners as in Patent Document 1, the resin constituting the insulating layers fails to fill the corners, making it likely for voids to occur.

In contrast, the interconnect substrate 1 is provided with the first cut-out 101 and the second cut-out 102 at the periphery of the glass core layer 10, such that the connecting portions between the side portions and the bottom portions are curved in cross-sectional view. The fact that the first cut-out 101 and second cut-out 102 do not have sharp corners reduces the likelihood that the resin constituting the insulating layers 13 and 23 fails to fill the corners. This arrangement makes it unlikely for voids to occur in the interconnect substrate 1, thereby effectively suppressing the internal fracture of the glass core layer 10.

The inventors of the present invention conducted experiments to confirm the effect of the first and second cut-outs in the interconnect substrate 1 and to check the presence or absence of voids.

First, glass core layers with a thickness of 1 mm were prepared, and 4 epoxy-resin insulating layers with a thickness of 30 μm were laminated on each side of each core layer to produce 9 samples of an interconnect substrate (which will hereinafter be referred to as Samples A). The core layer of each Sample A was provided with first and second cut-outs that were continuously formed all along the periphery, and the first and second cut-outs were covered with insulating layers. With respect to each Sample A, the connecting portions between the side portions and the bottom portions of the first and second cut-outs were inspected with a microscope image, which revealed the presence of curved shapes in cross-sectional view, as exemplified in FIG. 1B. In addition, the inspection of the microscope image confirmed that the first and second cut-outs were covered with the insulating layers, without the occurrence of voids.

Next, nine Samples B with the same layer structure as Samples A were prepared. The core layers of Samples B were not provided with the first and second cut-outs. That is, Samples A and B have the same technical specifications, except for whether or not the first cut-out and the second cut-out are provided.

The core layers of Samples A and B immediately after sample preparation were inspected with microscope images to determine whether the glass was fractured.

Two Samples A and two Samples B were subjected to a one-minute reflow process at 260° C. three times. The core layers of these Samples A and B after the reflow processes were inspected with microscope images to determine whether the glass was fractured.

Then, two other Samples A and two other Samples B were subjected to a one-minute reflow process at 260° C. five times. The core layers of these Samples A and B after the reflow processes were inspected with microscope images to check whether the glass was fractured.

Further, two other Samples A and two other samples B were subjected to a one-minute reflow process at 260° C. ten times. The core layers of these Samples A and B after the reflow processes were inspected with microscope images to determine whether the glass was fractured.

The inspection results are shown in Table 1. Table 1 exhibits the number of samples in which glass fracture was observed among the samples checked. For example, “½” indicates that two samples were checked and only one sample had glass failure.

TABLE 1

| | | IMMEDIATELY | | | |
|---|---|---|---|---|---|
| | | AFTER | | | |
| | FIRST | SAMPLE | | | |
| | CUT-OUT | PREPARATION | AFTER REFLOW | | |
| | SECOND | (BEFORE | THREE | FIVE | TEN |
| SAMPLE | CUT-OUT | REFLOW) | TIMES | TIMES | TIMES |
| A | PRESENT | 0/9 | 0/2 | 0/2 | 0/2 |
| B | NOT | 0/9 | 2/2 | 1/2 | 1/2 |
| | PRESENT | | | | |

As shown in Table 1, no fracture was observed in any of nine Samples A and nine Samples B immediately after sample preparation (before the reflow processes). In contrast, after the three reflow processes, no glass fracture was observed in Samples A having the first and second cut-outs, but glass fracture was observed in two out of two Samples B without the first and second cut-outs.

After the five reflow processes, no glass fracture was detected in Samples A having the first and second cut-outs, but glass fracture was detected in one out of two Samples B without the first and second cut-outs.

After the ten reflow processes were performed, Samples A having the first and second cut-outs had no glass fracture, but one out of two Samples B without the first and second cut-outs had glass fracture.

In this manner, forming along the periphery of the glass core layer the first and second cut-outs having the curved connecting portions between the side portions and the bottom portions in cross-sectional view was confirmed to effectively reduce glass fracture resulting from heat application.

### [Method of Making Interconnect Substrate]

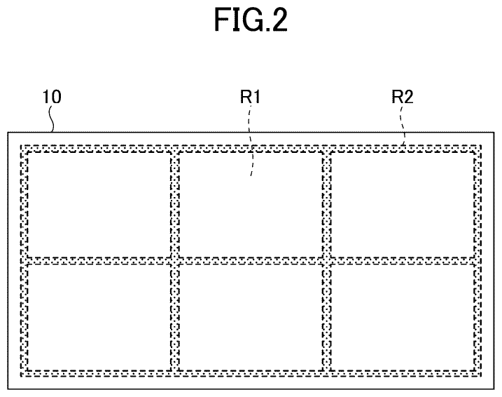

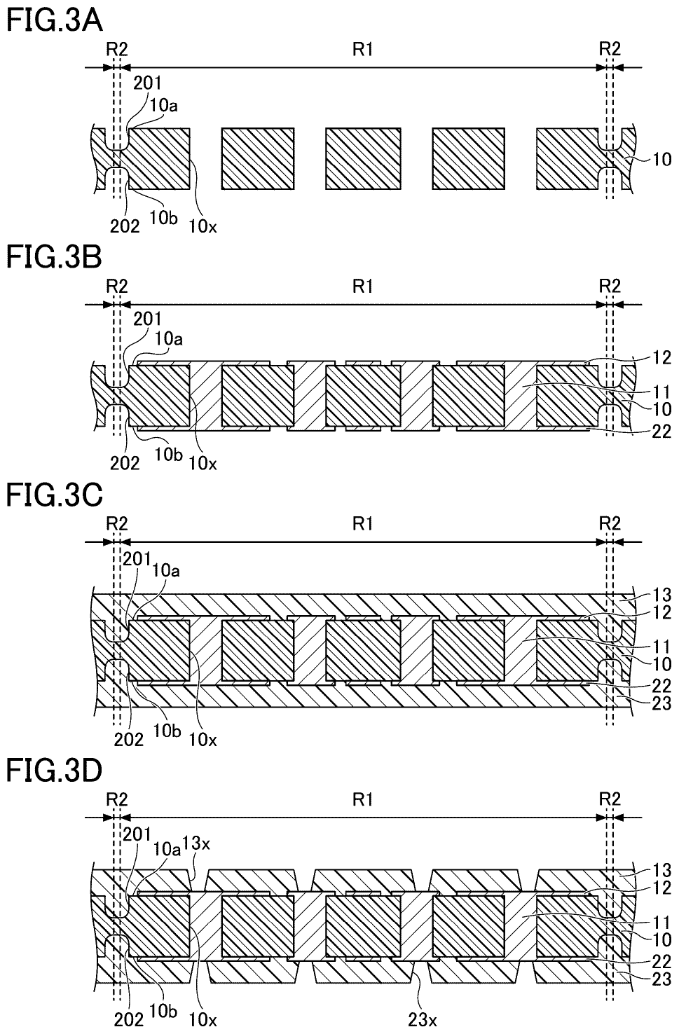

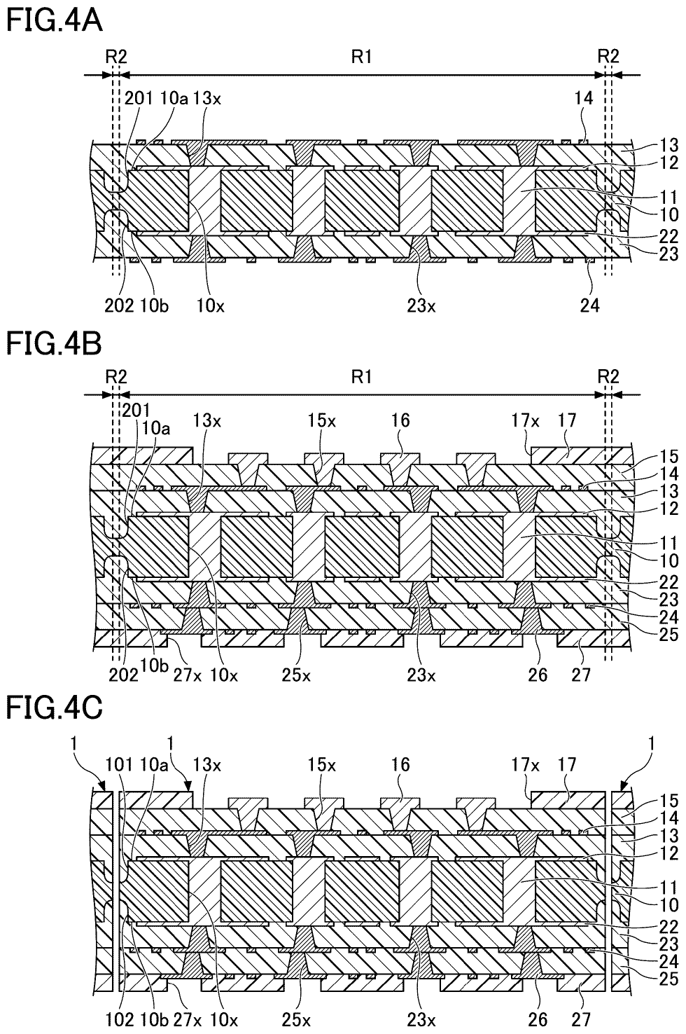

FIG. 2 through FIGS. 4A to 4C are drawings illustrating an example of the manufacturing process of the interconnect substrate according to the first embodiment. FIG. 2 is a plan view, and FIGS. 3A to 3D and FIGS. 4A to 4C are cross-sectional views.

First, in the step illustrated in FIG. 2, a glass core layer 10 is prepared. The core layer 10 includes a plurality of interconnect regions R1 that are singulated to form interconnect substrates, and a cutting region R2 along which a cut is made for singulation. FIG. 2 depicts the cutting region R2 in dot shading for convenience.

In the step illustrated in FIG. 3A, through holes 10x are formed in each interconnect region R1 of the core layer 10 by wet etching. Furthermore, a first groove 201 wider than the cutting region R2 is formed by wet etching at and around the cutting region R2 on the first surface 10a of the core layer 10. A second groove 202 wider than the cutting region R2 is formed by wet etching at and around the cutting region R2 on the second surface 10b of the core layer 10. The same etching solution may be used for the wet etching of the first groove 201, the second groove 202, and the through holes 10x. This effectively simplifies the manufacturing process of the interconnect substrate 1. Examples of the etching solution used in this process include hydrofluoric acid, strong alkali solution, and the like.

In plan view, the interconnect region R1 on the first surface 10a of the core layer 10 has a plurality of corners, and the first groove 201 includes at least a portion bent along each corner of the interconnect region R1 on the first surface 10a. The first groove 201 may be provided along the entire periphery of the interconnect region R1 on the first surface 10a. In plan view, the interconnect region R1 on the second surface 10b of the core layer 10 has a plurality of corners, and the second groove 202 includes at least a portion bent along each corner of the interconnect region R1 on the second surface 10b. The second groove 202 may be provided along the entire periphery of the interconnect region R1 on the second surface 10b. As the first groove 201 and the second groove 202 are formed by wet etching, the connecting portions between the side portions and the bottom portions of the first groove 201 and the second groove 202 are curved in cross-sectional view.

In the step illustrated in FIG. 3B, an interconnect layer 12 is disposed in each interconnect region R1 on the first surface 10a of the core layer 10, and an interconnect layer 22 is disposed in each interconnect region R1 on the second surface of the core layer 10, with through interconnects 11 formed in the through holes 10x. For example, a seed layer (copper or the like) covering the first surface 10a, the second surface 10b, and the inner wall surfaces of the through holes 10x of the core layer 10 is formed by electroless plating, sputtering, or the like, followed by forming an electrolytic plating layer (copper or the like) on the seed layer by electrolytic plating using the seed layer as a path to feed current. This arrangement fills the through holes 10x with the electrolytic plating layer formed on the seed layer, and forms the interconnect layers 12 and 22 each as a laminate of the seed layer and the electrolytic plating layer on the first surface 10a and the second surface 10b, respectively, of the core layer 10. Thereafter, the interconnect layers 12 and 22 are each patterned into a predetermined plan shape by a subtractive method or the like.

In the step illustrated in FIG. 3C, an insulating layer 13 covering the interconnect layer 12 and the first groove 201 is disposed in each interconnect region R1 and the cutting region R2 on the first surface 10a of the core layer 10. The insulating layer 13 is formed to cover the first groove 201. Specifically, for example, a semi-cured epoxy-based resin film or the like is laminated on the first surface 10a of the core layer 10 so as to cover the interconnect layer 12 and the first groove 201, and then cured to form the insulating layer 13. Alternatively, instead of laminating epoxy-based resin film or the like, epoxy-based resin or the like in liquid or paste form may be applied and then cured to form the insulating layer 13. The material and the thickness of the insulating layer 13 are as previously described. Similarly, an insulating layer 23 covering the interconnect layer 22 and the second groove 202 is disposed in each interconnect region R1 and the cutting region R2 on the second surface 10b of the core layer 10. The upper surface of the portion of the insulating layer 13 filling the first groove 201 and the upper surfaces of the other portions of the insulating layer 13 are, for example, coplanar. The lower surface of the portion of the insulating layer 23 filling the second groove 202 and the lower surfaces of the other portions of the insulating layer 23 are, for example, coplanar.

In the step illustrated in FIG. 3D, via holes 13x are formed in the insulating layer 13 to penetrate the insulating layer 13 and expose the upper surface of the interconnect layer 12. Also, via holes 23x are formed in the insulating layer 23 to penetrate the insulating layer 23 and expose the lower surface of the interconnect layer 22. The via holes 13x and 23x may be formed by a laser processing method using, for example, a CO₂ laser. After the via holes 13x and 23x are formed, desmearing treatment is preferably performed to remove resin residues adhering to the surfaces of the interconnect layers 12 and 22 exposed at the bottom of the via holes 13x and 23x.

In the step illustrated in FIG. 4A, an interconnect layer 14 is formed on the first side of the insulating layer 13. The interconnect layer 14 includes via interconnects filling the via holes 13x and an interconnect pattern formed on the upper surface of the insulating layer 13. The interconnect layer 14 is electrically connected to the interconnect layer 12 exposed at the bottom of the via holes 13x. Similarly, an interconnect layer 24 is formed on the second side of the insulating layer 23. The interconnect layer 24 includes via interconnects filling the via holes 23x and an interconnect pattern formed on the lower surface of the insulating layer 23. The interconnect layer 24 is electrically connected to the interconnect layer 22 exposed at the end of the via holes 23x. The materials of the interconnect layers 14 and 24 and the thicknesses of the interconnect patterns may be the same as those of the interconnect layer 12, for example.

In the step illustrated in FIG. 4B, substantially the same steps as in FIGS. 3C, 3D, and 4A are repeated to form insulating layers 15 and 25 and interconnect layers 16 and 26. Thereafter, a solder resist layer 17 is formed on the upper surface of the insulating layer 15 so as to cover the interconnect layer 16. Further, a solder resist layer 27 is formed on the lower surface of the insulating layer 25 so as to cover the interconnect layer 26. The solder resist layer 17 may be formed, for example, by applying a photosensitive epoxy-based insulating resin in liquid or paste form to the upper surface of the insulating layer 15 so as to cover the interconnect layer 16 by screen printing, roll coating, spin coating, or the like. Alternatively, a photosensitive epoxy-based insulating resin film, for example, may be laminated on the upper surface of the insulating layer 15 so as to cover the interconnect layer 16. The method of forming the solder resist layer 27 is substantially the same as that of the solder resist layer 17. Thereafter, the solder resist layers 17 and 27 are exposed and developed. As a result, an opening 17x is formed to expose the interconnect layer 16 outside the solder resist layer 17. Also, openings 27x for exposing portions of the lower surface of the interconnect layer 26 are formed in the solder resist layer 27.

In the step illustrated in FIG. 4C, all the layers, including the core layer 10, are cut along the cutting region R2 illustrated in FIG. 4B to produce a plurality of singulated interconnect substrates 1. The cutting can be performed by, for example, a dicer. The core layer 10 of each singulated interconnect substrate 1 has the first cut-out 101, as a divided half of the first groove 201, located on the outer side of the first surface 10a in plan view, and has a second cut-out 102, as a divided half of the second groove 202, located on the outer side of the second surface 10b in plan view. The insulating layer 13 fills the first cut-out 101, and the insulating layer 23 fills the second cut-out 102.

### Variations of First Embodiment

Variations of the first embodiment are directed to examples in which the positions of the first cut-out 101 and the second cut-out 102 are different from those in the interconnect substrate of the first embodiment. In connection with the variations of the first embodiment, descriptions of the same components as those of the already described embodiment may be omitted.

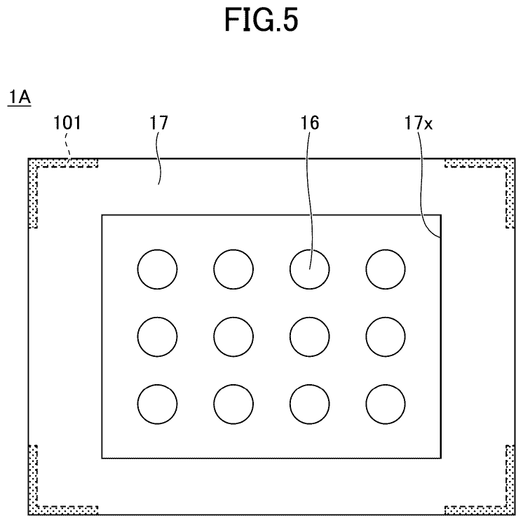

FIG. 5 is a plan view illustrating an example of an interconnect substrate according to the first variation of the first embodiment. An interconnect substrate 1A illustrated in FIG. 5 is configured such that first cut-outs 101 are separated from each other, and are each bent along the perimeter of a corresponding corner of the first surface 10a of the core layer 10. That is, the number of corners and the number of first cut-outs 101 are the same. Second cut-outs 102 may be, for example, provided at positions aligned with the first cut-outs 101 in plan view.

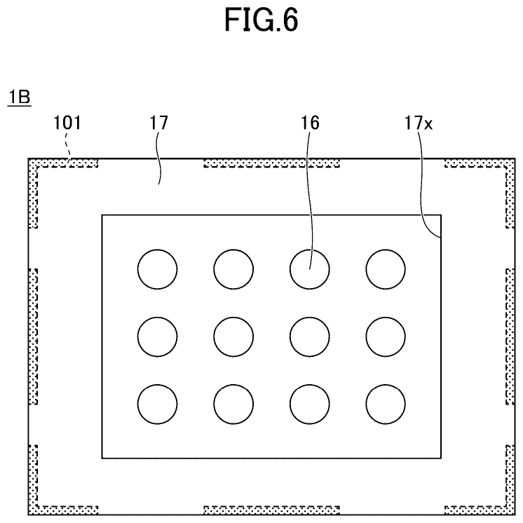

FIG. 6 is a plan view illustrating an example of an interconnect substrate according to the second variation of the first embodiment. An interconnect substrate 1B illustrated in FIG. 6 is configured such that first cut-outs 101 includes those provided at the same positions as in the interconnect substrate 1A and those provided between adjacent corners. In the interconnect substrate 1B, eight first cut-outs 101 spaced apart from each other are provided. The number of first cut-outs 101 spaced apart from each other may be greater. Second cut-outs 102 may be, for example, provided at positions aligned with the first cut-outs 101 in plan view.

As illustrated in FIGS. 5 and 6, as long as the first cut-outs 101 include a portion bent along the perimeter of each corner of the first surface 10a, it is not necessary to provide one continuous first cut-out 101 that extends all along the perimeter of the first surface 10a as in the first embodiment. Stress tends to concentrate on each corner of the first surface 10a and each corner of the second surface 10b when the temperature rises. Therefore, the function of suppressing internal fracture of the glass core layer 10 is effectively provided by providing the first cut-outs 101 including a portion bent along the perimeter of each corner of the first surface 10a and providing the second cut-outs 102 including a portion bent along the perimeter of each corner of the second surface 10b.

Although the preferred embodiments have been described in detail above, the present invention is not limited to the above-described embodiments, and various modifications and substitutions may be made to the above-described embodiments without departing from the scope of the claims.

For example, the present invention is also effective for an interconnect substrate having an interconnect layer and an insulating layer only on one side of the glass core layer. In this case, a cut-out may be provided only on one side of the core layer.

According to the disclosed technology, an interconnect substrate having a core layer made of glass is provided in which internal fractures in the glass are effectively suppressed.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

The present disclosures non-exhaustively contain subject matter as set out in the following clauses.

[Clause 1]A method of making an interconnect substrate, comprising:
providing a glass core layer having a plurality of interconnect regions for singulation into interconnect substrates and a cutting region along which a cut is to be made for the singulation;
forming, by wet etching, one or more first grooves each wider than the cutting region and each including the cutting region on one surface of the core layer;
disposing a first interconnect layer in each of the interconnect regions on the one surface of the core layer; and
disposing a first insulating layer covering the first interconnect layer and the one or more first grooves in each of the interconnect regions and the cutting region on the one surface of the core layer; and
wherein, in plan view, each of the interconnect regions on the one surface of the core layer has a plurality of corners, and the one or more first grooves include at least a portion bent along each of the corners of the interconnect regions on the one surface,
wherein, in a cross-sectional view of each of the one or more first grooves, a connecting portion between a side portion and a bottom portion is curved.

[Clause 2] The method according to clause 1, further comprising:
forming, by wet etching, one or more second grooves each wider than the cutting region and each including the cutting region on another surface of the core layer;
disposing a second interconnect layer in each of the interconnect regions on the another surface of the core layer; and
disposing a second insulating layer covering the second interconnect layer and the one or more second grooves in each of the interconnect regions and the cut region on the another surface of the core layer,
wherein, in plan view, each of the interconnect regions on the another surface of the core layer has a plurality of corners, and the one or more second grooves include at least a portion bent along each of the corners of the interconnect regions on the another surface, and
wherein in a cross-sectional view of each of the one or more second grooves, a connecting portion between a side portion and a bottom portion is curved.

[Clause 3] The method according to clause 2, further comprising producing the interconnect substrates by cutting along the cutting region,
wherein the core layer of each of the interconnect substrates has one or more first cut-outs, as a divided half of the one or more first grooves, located on an outer side of the one surface in plan view, and one or more second cut-outs, as a divided half of the one or more second grooves, located on an outer side of the another surface in plan view.

[Clause 4] The method according to clause 2, further comprising forming through holes penetrating the core layer by wet etching,
wherein a same etching solution is used for wet etching of the one or more first grooves, the one or more second grooves, and the through holes.

What is claimed is:

1. An interconnect substrate comprising:
a core layer made of glass; and
a first interconnect layer disposed on a surface of the core layer,
wherein the core layer has one or more first cut-outs located on an outer side of the surface in plan view,
wherein, in plan view, the surface of the core layer has a plurality of corners, and the one or more first cut-outs include at least a portion bent along each of the corners of the surface, and
wherein in a cross-sectional view of each of the one or more first cut-outs, a connection portion between a side portion and a bottom portion is curved.

2. The interconnect substrate according to claim 1, further comprising a first insulating layer disposed on the surface of the core layer and covering the first interconnect layer and the one or more first cut-outs.

3. The interconnect substrate according to claim 1, wherein, as the one or more first cut-outs, one cut-out is provided to extend all along a perimeter of the surface.

4. The interconnect substrate according to claim 1, further comprising a second interconnect layer disposed on another surface of the core layer,
wherein the core layer has one or more second cut-outs located on an outer side of the another surface in plan view,
wherein, in plan view, the another surface of the core layer has a plurality of corners, and the one or more second cut-outs include at least a portion bent along each of the corners of the another surface, and
wherein, in a cross-sectional view of each of the one or more second cut-outs, a connection portion between a side portion and a bottom portion is curved.

5. The interconnect substrate according to claim 4, further comprising a second insulating layer disposed on the another surface of the core layer and covering the second interconnect layer and the one or more second cut-outs.

6. The interconnect substrate according to claim 4, wherein, as the one or more second cut-outs, one cut-out is provided so as to extend all along a perimeter of the another surface.
